(19) United States
(12) Patent Application Publication
(10) Pub. No.: US 2024/0162341 A1
(43) Pub. Date: May 16, 2024

(54) DOUBLE CONTINUOUS GRADED BACK BARRIER GROUP III-NITRIDE HIGH ELECTRON MOBILITY HETEROSTRUCTURE

(71) Applicant: Raytheon Company, Waltham, MA (US)

(72) Inventors: Maher Bishara Tahhan, Tewksbury, MA (US); John Andrew Logan, Lawrence, MA (US)

(73) Assignee: Raytheon Company, Waltham, MA (US)

(21) Appl. No.: 18/054,990

(22) Filed: Nov. 14, 2022

(51) Int. Cl. H01L 29/778; H01L 21/02; H01L 29/20; H01L 29/205; H01L 29/207; H01L 29/66

(52) U.S. Cl. CPC H01L 29/7787; H01L 21/02376; H01L 21/02378; H01L 21/02381; H01L 21/02389; H01L 21/0242; H01L 21/02458; H01L 21/0254; H01L 21/02576; H01L 21/02579; H01L 29/2003; H01L 29/205; H01L 29/207; H01L 29/66462

(57) ABSTRACT

A high electron mobility heterostructure and a method of fabricating the heterostructure, wherein the high electron mobility heterostructure comprises a substrate, a buffer on the substrate, a doped charge compensation layer on the buffer, a double continuous grade barrier on the doped charge compensation layer having increasing polarization charge and decreasing polarization charge, a channel on the double continuous grade barrier, and a charge generation layer on the channel. The method comprises forming a substrate, forming a buffer on the substrate, forming a doped charge compensation layer on the buffer, forming a double continuous grade barrier on the doped charge compensation layer, forming a channel on the double continuous grade barrier, and forming a charge generation layer on the channel.

### STATEMENT OF GOVERNMENT INTEREST

This disclosure was made with United States Government support under Contract No. FA8650-18-C-7806 awarded by Department of Defense/Defense Advanced Research Projects Agency (DARPA). The United States Government has certain rights in this disclosure.

### BACKGROUND

Next generation high-charge high-electron-mobility devices (e.g., high-electron-mobility transistors (HEMTs) and diodes) presently suffer from elevated leakage current due to insufficient electron confinement. Current Scandium Aluminum Nitride (ScAlN) based HEMTs have high buffer leakage with its high charge density. The high buffer leakage may be due to poor backside confinement of the two-dimensional electron gas (2DEG). The buffer leakage may be two to three orders of magnitude greater than Aluminum Gallium Nitride (AlGaN) based Gallium Nitride (GaN) HEMTs. The higher buffer leakage reduces radio frequency (RF) efficiency and increases power loss.

FIG. 1 is an illustration of an exemplary prior art HEMT heterostructure 100 with a single back barrier layer. FIG. 2 is an illustration of an exemplary prior art HEMT heterostructure 200 with a single back barrier layer and a transition layer. FIG. 3 is a chart of energy and free carrier density versus position for the exemplary prior art HEMT heterostructures of FIGS. 1 and 2 that illustrates a parasitic 2DEG. The parasitic 2DEG increases leakage current and reduces maximum power in the HEMT devices. Current back barrier HEMT heterostructures do not fully eliminate parasitic 2DEG without requiring narrow tolerances for heterostructure dimensions or without reducing back barrier slope.

FIG. 4 is an illustration of an exemplary prior art HEMT heterostructure 400 with two back barriers. Each back barrier comprises AlGaN and has a single fixed percentage of Aluminum (Al) concentration, where the first back barrier has a lower concentration of Al than the second back barrier. FIG. 5 is a chart of an exemplary HEMT heterostructure of FIG. 4 where the first back barrier has a fixed 2% concentration of Al, and where the second back barrier has a fixed 5% concentration of Al.

Exact in-plane lattice matched conditions are difficult to achieve in heterojunctions having epitaxial growth and as a result there usually exists some degree of in-plane mismatch between different layers. When an epitaxial layer is grown on a crystalline substrate or on one or more epitaxial layers with a defined crystallinity, the in-plane lattice of the epitaxial layer will initially conform to match the in-plane lattice constant of the underlying material. However, the epitaxial layer experiences a tensile or compressive in-plane strain as it attempts to conform to the underlying in-plane lattice and the strain energy of the epitaxial layer increases until it becomes large enough to nucleate misfit dislocations. The formation of misfit crystal dislocations reduces the strain in the epitaxial layer and allows the in-plane lattice parameter to relax towards its bulk lattice structure above the interface. The thickness at which misfit dislocations are nucleated to relieve the strain in the epitaxial layer is known as the critical thickness for the layer. The larger the in-plane lattice mismatch, the smaller the critical thickness of the epitaxial layer. When the thickness of the epitaxial layer is less than the critical thickness, the epitaxial layer is said to be pseudomorphic. For Group III-Nitride based transistors, nearly matched in-plane lattices are desired between various layers to minimize misfit dislocations and defect formations.

### SUMMARY

In accordance with the concepts described herein, exemplary heterostructures and methods provide a pair of continuously graded pseudomorphic back barrier layers enabling a significantly steeper conduction band slope below a channel without forming a parasitic 2DEG, which improves electron confinement.

In accordance with the concepts described herein, exemplary heterostructures and methods provide a pair of pseudomorphic back barrier layers, where one of the pair of back barrier layers is continuously graded towards a Group III Nitride (III-N) alloy from a buffer material and the other of the pair of back barrier layers is continuously graded from a III-N alloy towards a channel material.

### DESCRIPTION OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Like reference numerals designate corresponding parts throughout the different views. Furthermore, embodiments are illustrated by way of example and not limitation in the figures, in which:

FIG. 1 is an illustration of an exemplary prior art HEMT heterostructure with a single back barrier;

FIG. 2 is an illustration of an exemplary prior art HEMT heterostructure with a single back barrier and a transition layer;

FIG. 3 is a chart of energy and free carrier density versus position for the exemplary prior art HEMT heterostructures of FIGS. 1 and 2;

FIG. 4 is an illustration of exemplary prior art HEMT heterostructure with two back barriers with a fixed Al concentration percentage in each back barrier;

FIG. 5 is a chart of the fixed percentage of Al concentration in each of the two back barriers of the prior art HEMT heterostructure of FIG. 4;

FIG. 6A is an illustration of exemplary high electron mobility heterostructure of the present disclosure;

FIG. 6B is an illustration of the exemplary high electron mobility device of FIG. 6A configured as a HEMT;

FIG. 6C is an illustration of the exemplary high electron mobility device of FIG. 6A configured as a diode;

FIG. 7A is a chart of the continuous percentage of Al concentration in each of the two back barriers of an exemplary high electron mobility heterostructure of FIG. 6A;

FIG. 7B is a chart of the continuous polarization grade in each of the two back barriers of another exemplary high electron mobility heterostructure of FIG. 6A;

FIG. 8 is a chart of energy and free carrier density versus position for an exemplary high electron mobility heterostructure of the present disclosure;

FIG. 9 is an illustration of a first alternative exemplary high electron mobility heterostructure of the present disclosure;

FIG. 10 is an illustration of a second alternative exemplary high electron mobility heterostructure of the present disclosure;

FIG. 11 is an illustration of a third alternative exemplary high electron mobility heterostructure of the present disclosure; and

FIG. 12 is an exemplary method of fabricating a high electron mobility heterostructure of the present disclosure.

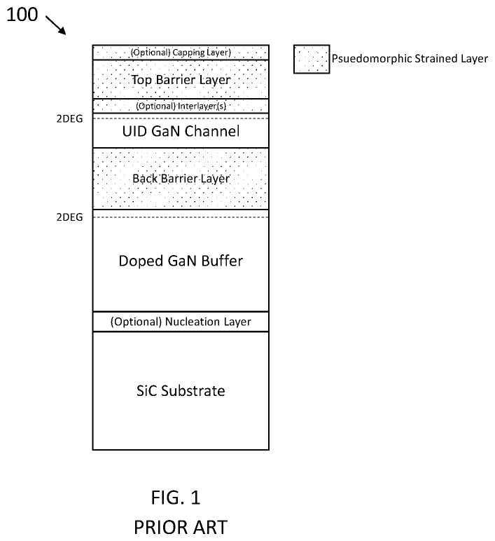

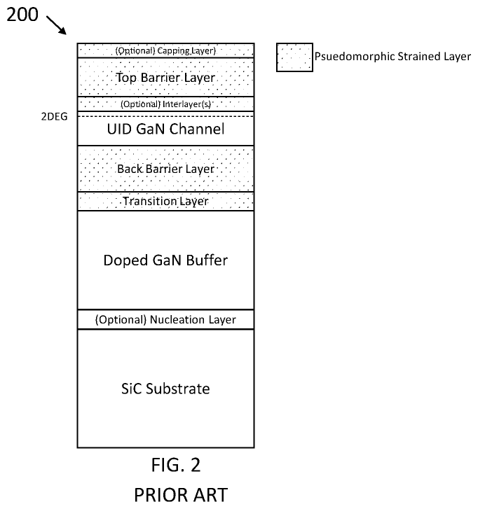

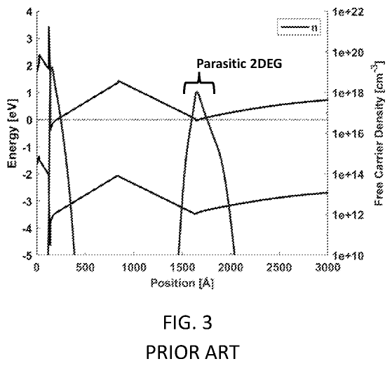

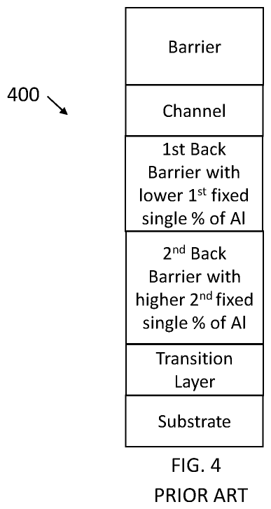

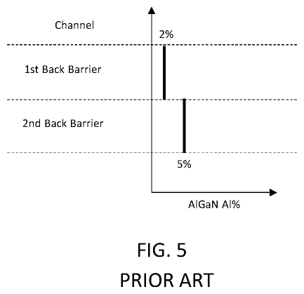

### DETAILED DESCRIPTION

The present disclosure provides a pair of pseudomorphic back barrier layers, where one of the pair of back barrier layers is continuously graded towards a Group III Nitride (III-N) alloy from a buffer material and the other of the pair of back barrier layers is continuously graded away from a III-N alloy to a channel material. Grading a material creates a quasi-field that affects the shape of the energy barrier to electrons. An amount of doping is added to the buffer material just below the pair of pseudomorphic back barrier layers to compensate for the quasi-field generated by the changing polarization of the pair of back barrier layers. The two continuous grades of the pair of back-barrier layers and compensation doping in the buffer material shapes the barrier in an advantageous manner by increasing 2DEG confinement via a higher back barrier conduction band slope. Polarization in a semiconductor is caused by an asymmetry in electron clouds in a crystal lattice. Polarization charge is the sum of spontaneous and piezoelectric polarization charges. Piezoelectric polarization charge is induced by strain applied to a material through the piezoelectric effect. A crystal can be tensile or compressively strained by growing it pseudomorphically with materials that have larger or narrower lattice constants. The amount of piezoelectric polarization charge depends on the strain which is a function of the material's lattice constant, the lattice constant of the materials around it, and how much this difference forces a deformation of the crystal. The spontaneous polarization charge is the dipole charge induced by the intrinsic asymmetry of the crystal lattice. This is present in crystals with a Wurtzite structure due to its asymmetry in the c direction of the crystal, and varies in value depending on the component atoms and their composition ratios. A continuous polarization grade in a material is where the material composition of a crystal is gradually adjusted as it is grown such that the polarization charge within the grade also changes in a gradual manner from each material composition to the next. An exemplary continuous polarization grade can be formed by changing the percentage of Al in an AlGaN layer as it is grown.

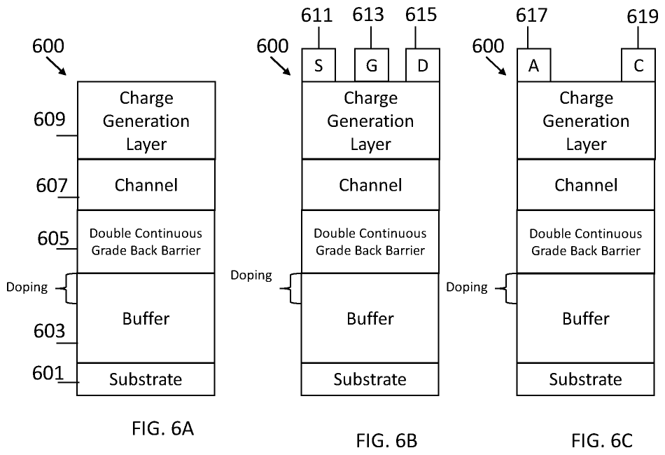

FIG. 6A is an illustration of exemplary high electron mobility heterostructure 600 of the present disclosure. In an exemplary embodiment, the high electron mobility heterostructure 600 comprises a substrate 601, a buffer 603 on the substrate 601, a double continuous grade back barrier 605 on the buffer 603, a channel 607 on the double continuous grade back barrier 605, and a charge generation layer 609 on the channel 607.

The buffer 603 may be doped near the boundary between the buffer 603 and the double continuous grade back barrier 605. Doping in the buffer 603 near the double continuous grade back barrier allows for band bending there to set the depletion depth in the buffer 603.

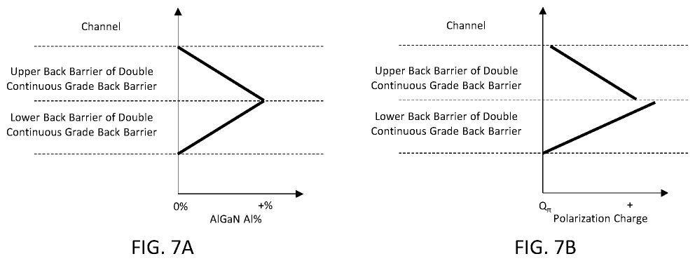

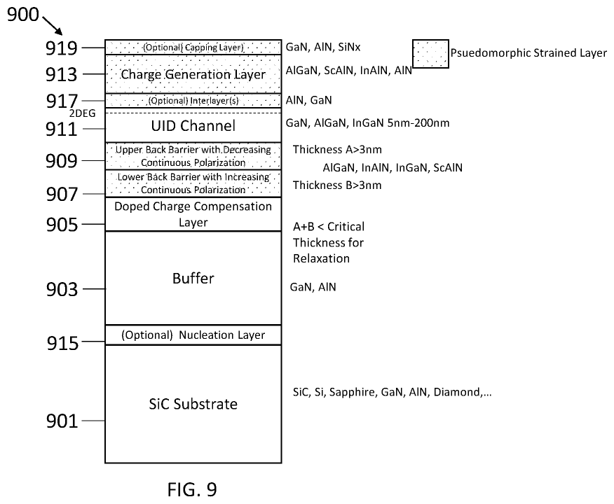

The double continuous grade back barrier 605 comprises a pair of continuously graded pseudomorphic back barrier layers which enables a significantly steeper conduction band slope below the channel 607 without a parasitic 2DEG as compared to prior art HEMT heterostructure, where the steeper conduction band slope improves 2DEG confinement. The double continuous grade back barrier 605 has a composition profile that increases the slope of the conduction band in the channel 607 and a higher tolerance for heterostructure dimensions that enable tuneability of the high electron mobility heterostructure 600. For example, the high electron mobility heterostructure 600 may have an increased back barrier slope, a thicker barrier, or a narrower channel while preventing a parasitic 2DEG. There is a directional change in the grading between the pair of back barrier layers (e.g., direction of change in the percentage of Al, or direction of change in the polarization charge). However, each of the pair of back barrier layers are continuous independently from each other. The double continuous grade back barrier is graded in two directions of change of polarization charge. For example, the lower of the pair of back barrier layers is continuously graded so that polarization charge becomes more positive, or increasing in the growth direction, while the upper of the pair of back barriers as illustrated in FIG. 9 is continuously graded so that polarization charge becomes more negative, or decreasing in the growth direction (e.g., as illustrated in FIG. 7B).

A double polarization grade in the present disclosure may be, for example, two independent continuous polarization grades that are adjacent. The first polarization grade (e.g., the lower back barrier 907 illustrated in FIG. 9) may have, for example, a monotonically changing polarization charge across the first polarization grade. The second polarization grade (e.g., the upper back barrier 907 illustrated in FIG. 9) may have, for example, a monotonically changing polarization charge across the second polarization grade with an opposite direction of change from the first polarization grade. A polarization grade may change monotonically (e.g., change in such a way as to generate progressively higher or lower values consistently, with no reversal).

FIG. 6B is an illustration of the exemplary high electron mobility device of FIG. 6A configured as a HEMT. In the exemplary HEMT 600, contacts 611, 613, and 615 are provided for a source, a gate, and a drain of the HEMT 600, respectively.

FIG. 6C is an illustration of the exemplary high electron mobility device of FIG. 6A configured as a diode. In the exemplary diode 600, contacts 617 and 619 are provided for an anode and a cathode of the diode 600, respectively.

FIG. 7A is a chart of the continuous percentage of Al concentration in an exemplary double continuous grade back barrier 605 of FIG. 6A. The double continuous grade back barrier 605 comprises a pair of back barriers, where each of the pair of back barriers has a continuous grading of Al percentage, and where the grading direction of the polarization charge in each of the two back barriers are opposite from each other. For example, FIG. 7A illustrates that a lower back barrier of the double continuous grade back barrier 605 in an AlGaN back barrier is graded from 0% Al to a positive rational number percentage of Al which is described in greater detail below with reference to FIGS. 9, 10, and 11. An upper back barrier of the double continuous grade back barrier 605 in an AlGaN back barrier is graded from a positive rational number percentage of Al to 0% Al which is also described in greater detail below with reference to FIGS. 9, 10, and 11.

FIG. 7B is a chart of the continuous change in polarization charge in another exemplary double continuous grade back barrier 605 of FIG. 6A. The double continuous grade back barrier 605 comprises a pair of back barriers, where each of the pair of back barriers has a continuous grading of polarization charge, where the grading direction of the polarization charge in each of the two back barriers are opposite from each other. For example, FIG. 7B illustrates that a lower back barrier of the double continuous grade back barrier 605 increases in polarization charge, which is described in greater detail below with reference to FIGS. 9, 10, and 11. An upper back barrier of the double continuous grade back barrier 605 decreases in polarization charge, which is also described in greater detail below with reference to FIGS. 9, 10, and 11.

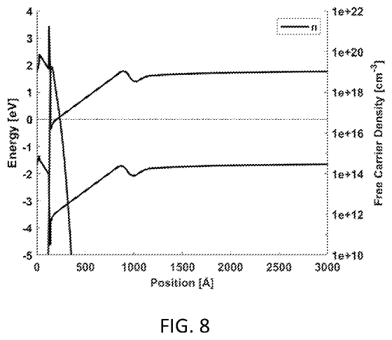

FIG. 8 is a chart of energy and free carrier density versus position for the exemplary high electron mobility heterostructure of FIG. 6A. The chart is for an exemplary embodiment of a GaN/AlGaN double continuous grade back barrier/GaN heterostructure with a linear 0-10%-0% AlGaN grade. That is, the exemplary embodiment has a lower back barrier of the double continuous grade back barrier with an exemplary Al percentage graded linearly from 0% to 10% and an upper back barrier of the double continuous grade back barrier with an exemplary Al percentage graded linearly from 10% to 0%.

FIG. 9 is an illustration of a first alternative exemplary high electron mobility heterostructure 900 of the present disclosure. The exemplary high electron mobility heterostructure 900 comprises a substrate 901, a buffer 903 on the substrate 901, a doped charge compensation layer 905 on the buffer 903, a lower continuously graded back barrier 907 with continuously increasing (e.g., monotonically increasing) polarization charge on the doped charge compensation layer 905, an upper continuously graded back barrier 909 with continuously decreasing (e.g., monotonically decreasing) polarization charge on the lower continuously graded back barrier 907, an unintentionally doped (UID) channel 911 on the upper continuously graded back barrier 909, and a charge generation layer 913 on the UID channel 911. Optionally, there may be at least one of a nucleation layer 915 between the substrate 901 and the buffer 903, at least one interlayer 917 between the UID channel 911 and the charge generation layer 913, and a capping layer 919 on the charge generation layer 913. The lower continuously graded back barrier 907, the upper continuously graded back barrier 909, the interlayer 917, the charge generation layer 913, and the capping layer 919 comprise pseudomorphically strained layers.

The substrate 901 may be Silicon (Si), Silicon Carbide (SiC), Sapphire, GaN, AlN, diamond, boron nitride (BN), or any other suitable substrate (e.g., SiC). The buffer 903 may be GaN or AlN or any other suitable material (e.g., GaN).

The lower continuously graded back barrier 907 may have a thickness greater than 3 nm. In an exemplary embodiment that includes Al in the lower continuously graded back barrier 907 (e.g., AlGaN), a percentage of Al in the lower continuously graded back barrier 907 may be continuously graded from a range of 0 to 5% Al and increasing (e.g., increasing monotonically) to a range of 2 to 30% Al. In an exemplary embodiment that includes Indium (In) but no Al in the lower continuously graded back barrier 907 (e.g., a back barrier of InGaN), a percentage of In in the lower continuously graded back barrier 907 may be continuously graded from a range of 5 to 100% In and decreasing (e.g., decreasing monotonically) to a range of 0 to 95% In. The upper continuously graded back barrier 909 may have a thickness greater than 3 nm. In an exemplary embodiment that includes Al in the upper continuously graded back barrier 909, a percentage of Al in the upper continuously graded back barrier 909 is continuously graded from a range of 2 to 30% Al and decreasing (e.g., decreasing monotonically) to a range of 0 to 5% Al. In an exemplary embodiment that includes Indium (In) but no Al in the upper continuously graded back barrier 909 (e.g., a back barrier of InGaN), a percentage of In in the upper continuously graded back barrier 909 may be continuously graded from a range of 0 to 95% In (e.g., GaN) and increasing (e.g., increasing monotonically) to a range of 5 to 100% In (e.g., InGaN). That is, the lower continuously graded back barrier 907 and the upper continuously graded back barrier 909 are graded in opposite directions from each other. The lower continuously graded back barrier 907 and the upper continuously graded back barrier 909 may be graded to identical percentages of material (e.g., 0% to 100% Al or In) but in opposite direction (e.g., 0% to 100% Al or In vs. 100% to 0% Al or In) or to different percentages of material (e.g., 0% to 100% Al or In vs. 95% to 5% Al or In) but in opposite directions (e.g., 0% to 100% vs. 95% to 5%), respectively. The total thickness of the lower continuously graded back barrier 907 and the upper continuously graded back barrier 909, which may be identical or different, are less than a critical thickness for relaxation. In the growth of pseudomorphically strained layers, the critical thickness is the thickness up to which relaxation does not occur and beyond which relaxation occurs by misfit dislocation formation.

The UID channel 911 may be GaN, AlGaN, or InGaN and have a thickness in the range from 5 nm to 200 nm. A 2DEG may be induced in the UID channel 911 by the charge generation layer 913. The charge generation layer 913 may be AlGaN, ScAlN, InAlN, InGaAlN, or AlN. The at least one interlayer 917 may be AlN or GaN. The capping layer 919 may be GaN, AlN, or SiNₓ, where x is a positive rational number.

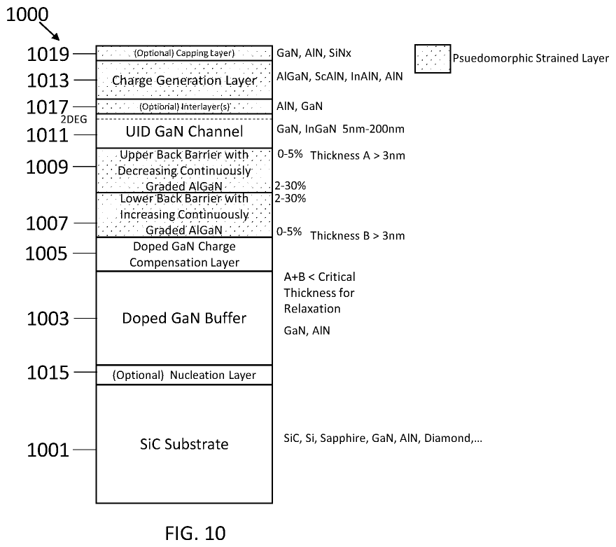

FIG. 10 is an illustration of a second alternative exemplary high electron mobility heterostructure 1000 of the present disclosure. The exemplary high electron mobility heterostructure 1000 comprises a substrate 1001, a doped buffer 1003 on the substrate 1001, a doped charge compensation layer 1005 on the doped buffer 1003, a lower continuously increasing (e.g., monotonically increasing) polarization charge graded back barrier 1007 on the doped charge compensation layer 1005, an upper continuously decreasing (e.g., monotonically decreasing) polarization charge graded back barrier 1009 on the lower continuously graded back barrier 1007, an unintentionally doped (UID) channel 1011 on the upper continuously graded back barrier 1009, and a charge generation layer 1013 on the UID channel 1011. Optionally, there may be at least one of a nucleation layer 1015 between the substrate 1001 and the doped buffer 1003, at least one interlayer 1017 between the UID channel 1011 and the charge generation layer 1013, and a capping layer 1019 on the charge generation layer 1013. The lower continuously graded back barrier 1007, the upper continuously graded back barrier 1009, the at least one interlayer 1017, the charge generation layer 1013, and the capping layer 1019 comprise pseudomorphically strained layers.

The substrate 1001 may be Silicon (Si), Silicon Carbide (SiC), Sapphire, GaN, AlN, diamond, boron nitride (BN), or any other suitable substrate (e.g., SiC). The doped buffer 1003 may be GaN or AlN, or any other suitable material (e.g., GaN). The doped charged compensation layer 1005 may be GaN.

The lower continuously graded back barrier 1007 may be AlGaN with a thickness greater than 3 nm, where a percentage of Al in the lower continuously graded back barrier 1007 is continuously graded from a range of 0 to 5% Al and increasing (e.g., increasing monotonically) to a range of 2 to 30% Al. The upper continuously graded back barrier 1009 may be AlGaN with a thickness greater than 3 nm, where a percentage of Al in the upper continuously graded back barrier 1009 is continuously graded from a range of 2 to 30% Al and decreasing (e.g., decreasing monotonically) to a range of 0 to 5% Al. That is, the lower continuously graded back barrier 1007 and the upper continuously graded back barrier 1009 are graded in opposite directions from each other. The lower continuously graded back barrier 1007 and the upper continuously graded back barrier 1009 may be graded to identical but opposite percentages of Al or to different but opposite percentages of Al. The total thickness of the lower continuously graded back barrier 1007 and the upper continuously graded back barrier 1009, which may be identical or different, are less than a critical thickness for relaxation. In the growth of pseudomorphically strained layers, the critical thickness is the thickness up to which relaxation does not occur and beyond which relaxation occurs by misfit dislocation formation.

The UID channel 1011 may be GaN, AlGaN, or InGaN (e.g., GaN) and have a thickness in the range from 5 nm to 200 nm. A 2DEG may be induced in the UID channel 1011 by the charge generation layer 1013. The charge generation layer 1013 may be AlGaN, ScAlN, InAlN, InGaAlN, or AlN. The at least one interlayer 1017 may be AlN or GaN. The capping layer 1019 may be GaN, AlN, or SiNₓ, where x is a positive rational number.

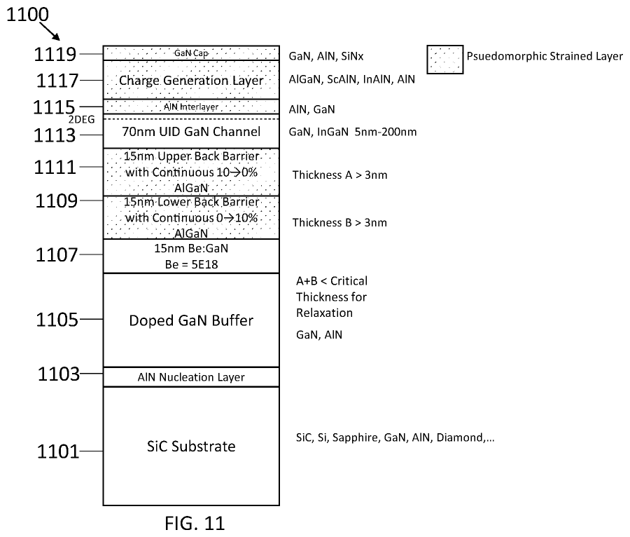

FIG. 11 is an illustration of a third alternative exemplary high electron mobility heterostructure 1100 of the present disclosure. The exemplary high electron mobility heterostructure 1100 comprises a substrate 1101, a nucleation layer 1103 on the substrate 1101, a doped buffer 1105 on the nucleation layer 1103, a doped charge compensation layer 1107 on the doped buffer 1105, a lower continuously increasing (e.g., monotonically increasing) polarization charge graded back barrier 1109 on the doped charge compensation layer 1107, an upper continuously decreasing (e.g., monotonically decreasing) polarization charge graded back barrier 1111 on the lower continuously graded back barrier 1109, an UID channel 1113 on the upper continuously graded back barrier 1111, at least one interlayer 1115 on the UID channel 1113, a charge generation layer 1117 on the at least one interlayer 1115, and a cap 1119 on the charge generation layer 1117. The lower continuously graded back barrier 1109, the upper continuously graded back barrier 1111, the at least one interlayer 1115, the charge generation layer 1117, and the cap layer 1119 comprise pseudomorphically strained layers.

The substrate 1101 may be Si, SiC, Sapphire, GaN, AlN, diamond, BN, or any other suitable substrate. The doped buffer 1105 may be GaN or AlN or any other suitable material (e.g., GaN). The doped charged compensation layer 1107 may be Beryllium (Be) doped GaN with a thickness of 15 nm. More generally, the doped charged compensation layer 1107 may be doped with Be, Magnesium (Mg), Iron (Fe), Carbon (C), Manganese (Mn), or other dopant in order to allow for band bending to match the quasi-field generated near the lower back barrier interface such that the buffer remains semi-insulating.

The lower continuously graded back barrier 1109 may be AlGaN with a thickness greater than 3 nm (e.g., 15 nm), where a percentage of Al in the lower continuously graded back barrier 1109 is continuously graded from a range of 0 to 5% (e.g., 0%) Al and increasing (e.g., increasing monotonically) to a range of 2 to 30% Al (e.g., 10%). The upper continuously graded back barrier 1111 may be AlGaN with a thickness greater than 3 nm (e.g., 15 nm), where a percentage of Al in the upper continuously graded back barrier 1111 is continuously graded from a range of 2 to 30% Al (e.g., 10%) and decreasing (e.g., decreasing monotonically) to a range of 0 to 5% Al (e.g., 0%). That is, the lower continuously graded back barrier 1109 and the upper continuously graded back barrier 1111 are graded in opposite directions from each other. The lower continuously graded back barrier 1109 and the upper continuously graded back barrier 1111 may be graded to identical percentages of Al but in opposite directions or to different percentages of Al but in opposite directions. The total thickness of the lower continuously graded back barrier 1109 and the upper continuously graded back barrier 1111, which may be identical or different, are less than a critical thickness for relaxation. In the growth of pseudomorphically strained layers, the critical thickness is the thickness up to which relaxation does not occur and beyond which relaxation occurs by misfit dislocation formation.

The UID channel 1113 may be GaN, AlGaN, or InGaN and have a thickness in the range from 5 nm to 200 nm (e.g., 70 nm GaN). An optional interlayer 1115 (e.g., and AlN interlayer) may separate the UID channel 1113 from the charge generation layer 1117. A 2DEG may be induced in the UID channel 1113 by the charge generation layer 1117. The barrier 1117 may be AlGaN, ScAlN, InAlN, InGaAlN, or AlN (e.g., ScAlN). The cap layer 1119 may be GaN, AlN, or SiNₓ (e.g., GaN), where x is a positive rational number.

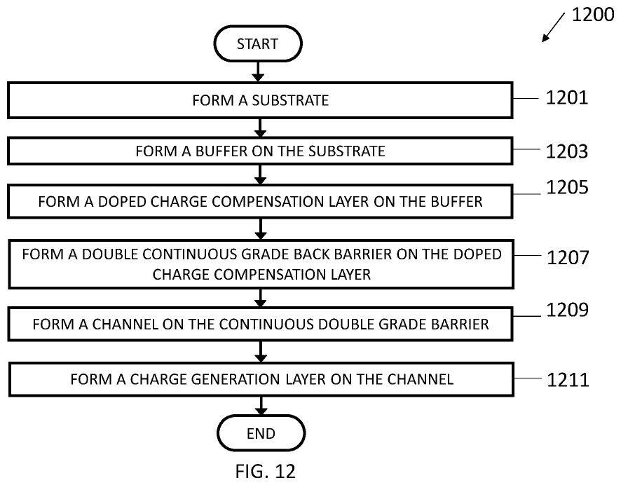

FIG. 12 is an exemplary method of fabricating a high electron mobility heterostructure (e.g., a HEMT or a high electron mobility diode) heterostructure of the present disclosure. The exemplary method 1200 comprises forming a substrate in step 1201. Step 1203 of the method 1200 comprises forming a buffer on the substrate. Step 1205 comprises forming a doped charge compensation layer on the buffer. Step 1207 comprises forming a double continuous grade barrier on the doped charge compensation layer. Step 1209 comprises forming a channel on the double continuous grade barrier. Step 1211 comprises forming a charge generation layer on the channel.

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable sub combination. Other embodiments not specifically described herein are also within the scope of the following claims.

Various embodiments of the concepts, systems, devices, structures and techniques sought to be protected are described herein with reference to the related drawings. Alternative embodiments can be devised without departing from the scope of the concepts, systems, devices, structures and techniques described herein.

It is noted that various connections and positional relationships (e.g., over, below, adjacent, etc.) are set forth between elements in the above description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “at least one” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection”.

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description herein, terms such as “upper,” “lower,” “right,” “left,” “vertical,” “horizontal, “top,” “bottom,” (to name but a few examples) and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements. Such terms are sometimes referred to as directional or positional terms.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways.

Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

What is claimed is:

1. A high electron mobility heterostructure, comprising:
a substrate;
a buffer on the substrate;
a doped charge compensation layer on the buffer;
a double continuous grade barrier on the doped charge compensation layer having increasing polarization charge and decreasing polarization charge;
a channel on the double continuous grade barrier; and
a charge generation layer on the channel.

2. The high electron mobility heterostructure of claim 1, wherein the substrate is one of Silicon (Si), Silicon Carbide (SiC), Sapphire, Gallium Nitride (GaN), Aluminum Nitride (AlN), Boron Nitride (BN), and diamond.

3. The high electron mobility heterostructure of claim 1, wherein the buffer is one of Gallium Nitride (GaN) and Aluminum Nitride (AlN).

4. The high electron mobility heterostructure of claim 1, wherein the doped charge compensation layer is Gallium Nitride (GaN) doped with at least one of Beryllium, Magnesium, Iron, Carbon, and Manganese.

5. The high electron mobility heterostructure of claim 1, wherein the double continuous grade barrier comprises:
a first Aluminum Gallium Nitride (AlGaN) barrier layer with an Aluminum (Al) content graded from a first range of 0% to 5% to a second range of 2% to 30% having monotonically increasing polarization charge; and
a second AlGaN barrier layer on the first AlGaN barrier layer with an Aluminum (Al) content graded from a first range of 2% to 30% to a second range of 0% to 5% having monotonically decreasing polarization charge.

6. The high electron mobility heterostructure of claim 5, wherein the first range of the first AlGaN barrier layer comprises one of: same as the second range of the second AlGaN barrier layer and different from the second range of the second AlGaN barrier layer; and
wherein the second range of the first AlGaN barrier layer comprises one of: same as the first range of the second AlGaN barrier layer and different from the first range of the second AlGaN barrier layer.

7. The high electron mobility heterostructure of claim 5, wherein first AlGaN barrier layer has a thickness greater than 3 nm, wherein the second AlGaN barrier layer has a thickness greater than 3 nm, wherein the thickness of the first barrier layer is one of: same as and different from the thickness of the second barrier layer, and wherein a thickness of a combination of the first AlGaN barrier layer and the second AlGaN barrier layer has a thickness less than a critical thickness for relaxation.

8. The high electron mobility heterostructure of claim 1, wherein the channel is an unintentionally doped channel that is one of Gallium Nitride (GaN) and Indium Gallium Nitride (InGaN).

9. The high electron mobility heterostructure of claim 1, wherein the charge generation layer is one of Aluminum Gallium Nitride (AlGaN), Scandium Aluminum Nitride (ScAlN), Indium Aluminum Nitride (InAlN), Indium Aluminum Gallium Nitride (InAlGaN), and Aluminum Nitride (AlN).

10. The high electron mobility heterostructure of claim 1, furth comprising:
a nucleation layer between the substrate and the buffer;
at least one interlayer between the channel and the charge generation layer; and
a capping layer on the charge generation layer, wherein the at least one interlayer is one of Aluminum Nitride (AlN) and Gallium Nitride (GaN), and wherein the capping layer is one of GaN, AlN, and Silicon Nitride (SiNₓ), where x is a positive rational number.

11. A method of fabricating a high electron mobility heterostructure, comprising:
forming a substrate;
forming a buffer on the substrate;
forming a doped charge compensation layer on the buffer;
forming a double continuous grade barrier on the doped charge compensation layer having increasing polarization charge and decreasing polarization charge;
forming a channel on the double continuous grade barrier; and
forming a charge generation layer on the channel.

12. The method of claim 11, wherein the substrate is one of Silicon (Si), Silicon Carbide (SiC), Sapphire, Gallium Nitride (GaN), Aluminum Nitride (AlN), Boron Nitride (BN), and diamond.

13. The method of claim 11, wherein the buffer is one of Gallium Nitride (GaN) and Aluminum Nitride (AlN).

14. The method of claim 11, wherein the doped charge compensation layer is Gallium Nitride (GaN) doped with at least one of Beryllium, Magnesium, Iron, Carbon, and Manganese.

15. The method of claim 11, wherein the double continuous grade barrier comprises:
a first Aluminum Gallium Nitride (AlGaN) barrier layer with an Aluminum (Al) content graded from a first range of 0% to 5% to a second range of 2% to 30% having monotonically increasing polarization charge; and
a second AlGaN barrier layer on the first AlGaN barrier layer with an Aluminum (Al) content graded from a first range of 2% to 30% to a second range of 0% to 5% having monotonically decreasing polarization charge.

16. The method of claim 15, wherein the first range of the first AlGaN barrier layer comprises one of same as the second range of the second AlGaN barrier layer and different from the second range of the second AlGaN barrier layer; and
wherein the second range of the first AlGaN barrier layer comprises one of same as the first range of the second AlGaN barrier layer and different from the first range of the second AlGaN barrier layer.

17. The method of claim 15, wherein first AlGaN barrier layer has a thickness greater than 3 nm, wherein the second AlGaN barrier layer has a thickness greater than 3 nm, wherein the thickness of the first barrier layer is one of: same as and different from the thickness of the second barrier layer, and wherein a thickness of a combination of the first AlGaN barrier layer and the second AlGaN barrier layer has a thickness less than a critical thickness for relaxation.

18. The method of claim 11, wherein the channel is an unintentionally doped channel that is one of Gallium Nitride (GaN) and Indium Gallium Nitride (InGaN).

19. The method of claim 11, wherein the charge generation layer is one of Aluminum Gallium Nitride (AlGaN), Scandium Aluminum Nitride (ScAlN), Indium Aluminum Nitride (InAlN), Indium Aluminum Gallium Nitride (InAlGaN), and Aluminum Nitride (AlN).

20. The method of claim 11, further comprising:
a nucleation layer between the substrate and the buffer;
at least one interlayer between the channel and the charge generation layer; and
a capping layer on the charge generation layer, wherein the at least one interlayer is one of Aluminum Nitride (AlN) and Gallium Nitride (GaN), and wherein the capping layer is one of GaN, AlN, and Silicon Nitride (SiNₓ), where x is a positive rational number.
